(19) United States
(12) Patent Application Publication
(10) Pub. No.: US 2026/0328844 A1
(43) Pub. Date: Oct. 22, 2026

(54) METHOD FOR EVALUATING CHANGE IN ELECTRICAL CONTACT OF A TRANSFER SWITCH

(71) Applicant: Schneider Electric USA, Inc., Boston, MA (US)

(72) Inventor: Ricardo DaSilveira, Florham Park, NJ (US)

(21) Appl. No.: 19/055,239

(22) Filed: Feb. 17, 2025

(51) Int. Cl. G01R 31/327

(52) U.S. Cl. CPC G01R 31/327

(57) ABSTRACT

The present disclosure is directed to methods and systems for evaluating the change in electrical contact of a transfer switch utilizing a multi-phase AC signal from the transfer switch. The present disclosure is further directed to the creation of a harmonized digital signal which reports the change in digital signal level due to change in contact of the transfer switch and allows for real-time evaluation and monitoring.

### FIELD

The present disclosure relates to the field of transfer switches and the evaluation of the change in electrical contact of a transfer switch using the AC (alternating current) signal present in the switch. The evaluation of change in electrical contact relates in certain embodiments to the main contacts of the transfer switches, which are the contacts that deliver the current or power to the connected or intended electrical load.

### BACKGROUND

A transfer switch is a switch that is generally used for transitioning electrical power consumed by a circuit from one power source to another power source. For example, a transfer switch is typically used to transfer the load of the circuit from a normal power source to a backup power source in the event of an emergency.

Currently, the evaluation of transfer switches (e.g., to perform diagnostic testing and determine whether the switch is making the transfer with the desired speed and accuracy) is done by invasive placement of a device into the system. For example, a device may be wired into the system such that it can inject 24 volts (V) into the switch and evaluate the output. This requires significant rewiring of the system/switch and is invasive in such a way that the evaluation device must be removed after testing. Further, this testing scheme provides relatively slow feedback. Problematically, these previous methods of evaluation are not suitable for continuous evaluation of the transfer switch, remote diagnostics, or real-time evaluation of the switch.

Therefore, a need exists for methods and systems for non-invasive, continuous, and/or remote methods for evaluation of a transfer switch.

### BRIEF SUMMARY

One embodiment of the present disclosure is directed to a method for detecting change in electrical contact of a transfer switch, wherein the transfer switch carries an analog multi-phase alternating current (AC) signal. The method comprises measuring a first phase of the analog multi-phase AC signal from the transfer switch; measuring a second phase of the analog multi-phase AC signal from the transfer switch; digitizing the measured analog first phase signal and the measured analog second phase signal to create a digitized first phase signal and a digitized second phase signal, respectively; and preparing a harmonized digital signal from the digitized first phase signal and digitized second phase signal. The harmonized digital signal is prepared such that the harmonized digital signal is at a first level when the digitized first phase signal and digitized second phase signal are both at a first level; the harmonized digital signal is at a second level when the digitized first phase signal and digitized second phase signal are both at a second level; and the harmonized digital signal is at the first level when the digitized first phase signal and digitized second phase signal are at different levels.

Other embodiments of the present disclosure are directed to a harmonization device. The harmonization device may comprise circuitry configured to receive a first phase digital signal and second phase digital signal, wherein the first phase digital signal and second phase digital signal are digitized from a first phase analog signal and a second phase analog signal, respectively, of an analog multi-phase alternating current (AC) signal carried by a transfer switch; compare the digitized first phase signal and digitized second phase signal; and prepare a harmonized digital signal. The harmonized digital signal may be prepared such that the harmonized digital signal is at a first level when the digitized first phase signal and digitized second phase signal are both at a first level; the harmonized digital signal is at a second level when the digitized first phase signal and digitized second phase signal are both at a second level; and the harmonized digital signal is at the first level when the digitized first phase signal and digitized second phase signal are at different levels.

Still further embodiments of the present disclosure are directed to systems for evaluating the change in electrical contact of a transfer switch, wherein the transfer switch carries an analog multi-phase alternating current (AC) signal. The system comprises a measurement device configured to measure a first phase and a second phase of the analog multi-phase AC signal carried by the transfer switch; an analog-to-digital conversion device configured to convert the measured analog first phase signal and the measured analog second phase signal to a digitized first phase signal and a digitized second phase signal, respectively; and a harmonization device comprising circuity configured to compare the digitized first phase signal and the digitized second phase signal and prepare a harmonized digital signal. The harmonized digital signal may be prepared such that the harmonized digital signal is at a first level when the digitized first phase signal and digitized second phase signal are both at a first level; the harmonized digital signal is at a second level when the digitized first phase signal and digitized second phase signal are both at a second level; and the harmonized digital signal is at the first level when the digitized first phase signal and digitized second phase signal are at different levels.

Other objects and features will be in part apparent and in part pointed out hereinafter.

### BRIEF DESCRIPTION OF THE SEVERAL VIEWS OF THE DRAWING

FIG. 1 illustrates an exemplary method for evaluating change in electrical contact of a transfer switch comprising preparing a harmonized digital signal.

FIG. 2 illustrates an exemplary method for evaluating change in electrical contact of a transfer switch, wherein a diagnostic device is present for evaluating and/or processing a harmonized digital signal.

FIG. 3 illustrates the conversion of an analog high voltage AC signal to a digitized AC signal.

FIG. 4 illustrates the conversion of two phases of an analog high voltage AC signal to their respective digitized AC signals, with particular emphasis on the zero crossing points of each phase.

FIG. 5 illustrates the conversion of two phases of an analog high voltage AC signal to a single digitized AC signal (i.e. “harmonized” digital signal) wherein the zero crossings of each phase are not shown in the harmonized digitized AC signal.

FIG. 6 illustrates harmonization device circuity in a Schmitt Trigger configuration.

FIG. 7 illustrates harmonization device circuitry comprising bi-directional optical couplers (optocouplers).

FIG. 8 illustrates harmonization device circuitry comprising multiple optocouplers.

FIG. 9 illustrates harmonization device circuitry comprising a processor and memory coupled to the processor.

Corresponding reference characters indicate corresponding parts throughout the drawings.

### DETAILED DESCRIPTION

The present disclosure is directed to methods and systems for evaluating the change in electrical contact of a device. For example, the change in electrical contact may be that of a transfer switch. Still further embodiments are directed to methods and systems for evaluating change in electrical contact of a transfer switch.

A transfer switch is typically used to switch a circuit from one power source to another. For example, the transfer switch may switch the circuit from a main power source to an emergency power source. In some situations, it may be desirable to have a delay in the switching from one power source to another. For example, the transfer switch or programming thereof may be designed such that the transfer switch removes contact of the circuit to a first power source/load source, waits for a predetermined period of time, and then contacts the circuit to a second power source/load source. This may be desirable in certain situations where the circuit is particularly sensitive and any overpowering of the circuit (i.e., by both power sources being connected for an overlapping period of time) may damage the circuit or equipment thereof. For example, if the transfer from one power source to another is too fast, the arcing created by the lifting of the electrical contact may create a short between the power sources. In certain configurations, such a result may be catastrophic to the system.

In other embodiments, it may be desirable to ensure that there is an overlapping period of time wherein the circuit is connected to both the first power source and the second power source. For example, this may arise where any interruption in power may cause the circuit or equipment thereof to be damaged or power off.

In either situation, it is important to evaluate and understand the time it takes the load of the circuit to be connected from one power source to another power source. This may be referred to herein interchangeably as the hot-hot measurement/time or the transfer measurement/time.

In the past, the measurement and evaluation of the transfer of a transfer switch required an invasive process wherein sensor(s) were wired into the transfer switch and relevant circuity and a low voltage (e.g., 24 V) was introduced into the system for measurement. In order for personnel to perform this invasive testing, it was necessary to create special procedures and training protocols to ensure proper testing. The risks associated with the testing deviating from the designed protocol, and the associated serious consequences of such a deviation, further contributed to a desire to devise a different testing protocol/procedure. For example, if the operator mistakenly mixed the high voltage with the lower 24 V DC voltage signal there was a risk of electrocution. Additionally, this was a relatively invasive solution that required there be adequate physical space around the transfer switch to appropriately connect the sensor(s) and device(s). In addition to the physical limitations of such a solution, the feedback from this design was also unacceptably slow for certain situations. These previous methods and configurations typically took several minutes to measure and report relevant results. Such a long period of time is not suitable for real-time diagnostics or evaluation of a transfer switch.

One goal of the present disclosure was to devise methods, systems, and devices for evaluating a transfer switch wherein the methods and tools were less invasive and could report accurate results in an exceedingly short amount of time (e.g., 0.1 milliseconds or less). An additional goal of these new methods, systems, and devices was to ensure a safer testing protocol for the operator with less possibility of operator error (e.g., no need to change or rewire the transfer switch).

It was surprisingly discovered that the high voltage (e.g., up to about 600 V) already present at the transfer switch (i.e. carried by the transfer switch) during standard operation could be used as a basis for evaluating the status and change in electrical contact of a transfer switch.

As used herein, the term “high voltage” is intended to refer to an AC RMS signal that is about 50 volts (V) or greater, about 100 V or greater, about 200 V or greater, about 300 V or greater, about 400 V or greater, about 500 V or greater, about 600 V or greater, about 700 V or greater, about 800 V or greater, about 900 V or greater, or about 1,000 V or greater. For example, an AC RMS signal that is from about 50 V to about 1,500 V, from about 50 V to about 1,250 V, from about 50 V to about 1,000 V, from about 50 V to about 900 V, from about 50 V to about 800 V, from about 50 V to about 700 V, from about 50 V to about 600 V, from about 55 V to about 600 V, from about 60 V to about 600 V, from about 70 V to about 500 V, from about 75 V to about 500 V, from about 80 V to about 500 V, from about 85 V to about 500 V, from about 90 V to about 500 V, or from about 100 V to about 500 V. In other embodiments, the term “high voltage” is intended to refer to a peak AC signal that is about 100 volts (V) or greater, about 200 V or greater, about 300 V or greater, about 400 V or greater, about 500 V or greater, about 600 V or greater, about 700 V or greater, about 800 V or greater, about 900 V or greater, or about 1,000 V or greater. For example, a peak AC signal that is from about 50 V to about 1,500 V, from about 60 V to about 1,500 V, from about 70 V to about 1,500 V, from about 80 V to about 1,500 V, from about 90 V to about 1,500 V, from about 100 V to about 1,500 V, from about 100 V to about 1,400 V, from about 100 V to about 1,300 V, from about 100 V to about 1,200 V, from about 100 V to about 1,100 V, or from about 100 V to about 1,000 V.

In some embodiments, the voltage carried by the transfer switch is an AC voltage. In other embodiments, the voltage carried by the transfer switch is a multi-phase AC voltage. In still further embodiments, the voltage carried by the transfer switch is a single-phase AC voltage, but is converted to a multi-phase AC voltage prior to measurement and/or conducting the methods described herein.

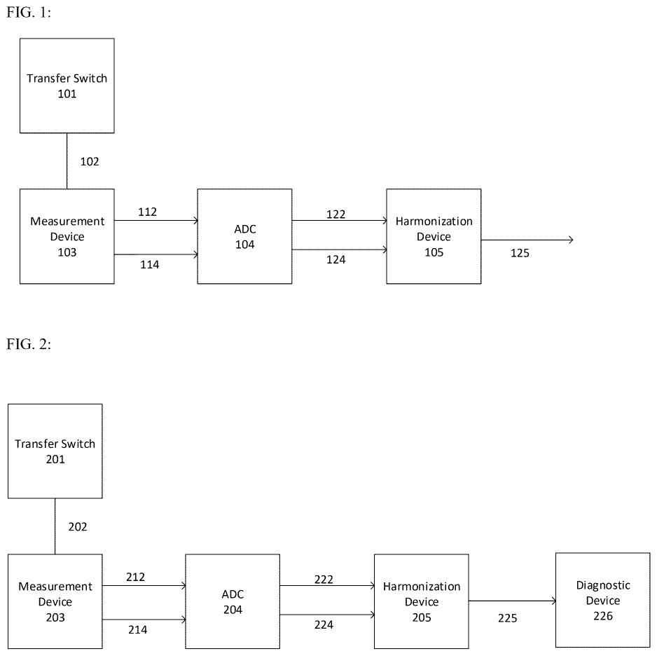

Referring now to FIG. 1, a method and system for evaluating the change in electrical contact of a transfer switch 101 is shown. The transfer switch 101 carries an analog multi-phase AC (alternating current) signal. A measurement device 103 is configured to measure a first phase and a second phase of the analog multi-phase AC signal from the transfer switch via connection point 102. For example, in one embodiment, a control panel harness is present at or near the transfer switch, and already configured to sense high voltage from the transfer switch. That is, the transfer switch is connected to a control panel harness such that the control panel harness acts as a connection point 102 between the transfer switch 101 and measurement device 103. In another embodiment, sensing leads are placed on the load point of a transfer switch bus, such that the sensing leads act as the connection point 102 between the transfer switch and the measurement device 103. In still other embodiments, the transfer switch 101 may be connected to the measurement device 103 by any suitable connection point 102, wherein no external voltage is introduced via the connection point to evaluate the transfer switch.

The measured analog first phase signal 112 and the measured analog second phase signal 114 are transmitted to an analog-to-digital (ADC) conversion device, wherein the ADC conversion device converts the measured analog first phase signal 112 to a digitized first phase signal 122 and converts the measured analog second phase signal 114 to a digitized second phase signal 124. The digitized first phase signal 122 and digitized second phase signal 124 are then transmitted to a harmonization device 105. The harmonization device 105 compares the digitized first phase signal and digitized second phase signal to determine whether changes in the level of the digitized signals are either attributable to a zero crossing of the digitized first phase signal and/or the digitized second phase signal or attributable to a switching in electrical contact of the transfer switch. In certain embodiments, for example as shown in FIG. 1, the harmonization device 105 is further configured to compare the digitized first phase signal and digitized second phase signal to produce a harmonized digital signal (i.e. clean hot-hot signal) 125. The digitized first phase signal and digitized second phase signal are compared to produce a harmonized digital signal that contains changes in signal level only attributable to the switching in electrical contact of the transfer switch. That is, the harmonized digital signal does not contain changes in signal level that would correspond to the zero crossing of the digitized first phase signal and/or digitized second phase signal.

For example, in one embodiment, the harmonization device 105 produces a harmonized digital signal 125 that is at a first level when the digitized first phase signal and digitized second phase signal are both at a first level; that is at a second level when the digitized first phase signal and digitized second phase signal are both at a second level; and that is at the first level when the digitized first phase signal and digitized second phase signal are at different levels.

Although discussion herein is directed to signals at a first level and second level, it will be understood that the values of the levels may differ depending on the configuration (e.g., polarity) of the system. For example, in one embodiment, the first level represents a high digital signal and the second level represents a low digital signal. In another embodiment, the first level represents a low digital signal and the second level represents a high digital signal. Where discussion herein is directed to a configuration having a first level that is high and second level that is low, it will be understood that the opposite configuration is also possible (e.g., a first level that is low and second level that is high). Regardless of the status of the first level and second level as high or low digital signals, the inventors have discovered that a harmonized digital signal prepared as described herein allows for a determination of the status of the transfer switch (i.e. whether the transfer switch is open or closed) and other diagnostic evaluations of the transfer switch.

In one embodiment, the harmonization device 105 comprises circuity configured to receive a first phase digital signal and second phase digital signal, compare the digitized first phase signal and digitized second phase signal, and prepare a harmonized digital signal.

In certain embodiments, the harmonization device circuity comprises a processor, an operational amplifier (opamp), an optical coupler (optocoupler), a transistor, or combinations thereof. In one embodiment, the harmonization device circuity comprises a microprocessor. In another embodiment, the harmonization device may be a discrete logic gate (e.g., AND logic gate).

For example, in some embodiments, the harmonization device comprises a processor and a memory coupled to the processor, the memory having computer-executable instructions stored thereon, wherein the instructions, when executed by the processor, cause the processor to receive a first phase digital signal and second phase digital signal, wherein the first phase digital signal and second phase digital signal are digitized from a first phase analog signal and a second phase analog signal, respectively, of an analog multi-phase AC signal carried by the transfer switch; and compare the digitized first phase signal and digitized second phase signal. As shown in FIG. 1, the harmonization device 105 is further configured such that the instructions, when executed by the processor, further cause the processor to prepare a harmonized digital signal: wherein the harmonized digital signal is at a first level when the digitized first phase signal and digitized second phase signal are both at a first level; wherein the harmonized digital signal is at a second level when the digitized first phase signal and digitized second phase signal are both at a second level; and wherein the harmonized digital signal is at the first level when the digitized first phase signal and digitized second phase signal are at different levels. In this way, the harmonized digital signal 125 does not contain any changes in digital signal level attributable to the zero crossings of the digitized first phase signal and/or digitized second phase signal.

As shown in FIG. 2, in certain embodiments, the harmonized digital signal 225 may be directed to a diagnostic device 226. The diagnostic device 226 may be configured to evaluate and/or process the harmonized digital signal 225 and to inform the operator of the time at which a change in electrical contact of the transfer switch takes place, to determine the frequency or speed of any change in electrical contact of the transfer switch, etc.

As explained elsewhere herein, the harmonized digital signal 225 may be prepared from a comparison of a digitized first phase signal and a digitized second phase signal. In certain embodiments, a first level of the harmonized digital signal represents a high digital signal and the second level of the harmonized digital signal represents a low digital signal, a change of the harmonized digital signal from the first level to the second level represents an opening of one or more contacts the transfer switch, and a change of the harmonized digital signal from the second level to the first level represents a closing of one or more contacts the transfer switch. As the harmonized digital signal 225 has been prepared such that it reports the opening and closing of the transfer switch, it is possible to process and/or evaluate the harmonized digital signal to determine the status of the transfer switch contacts. In other embodiments, this harmonized digital signal may be processed and/or evaluated to prepare diagnostic information regarding the transfer switch.

The diagnostic device may be any device suitable for determining or evaluating when a change in electrical contact of the transfer switch takes place, the frequency or speed of any change in electrical contact of the transfer switch, etc. For example, the diagnostic device 226 may comprise circuity configured to evaluate the harmonized digital signal. In other embodiments, the diagnostic device 226 comprises circuity configured to measure the time between an opening of the one or more transfer switch electrical contact(s) and a closing of the one or more transfer switch electrical contact(s). In another embodiment, the diagnostic device 226 comprises circuity configured to determine the time at which the one or more electrical contacts of the transfer switch are removed (i.e. lifted) or connected. In still further embodiments, the diagnostic device is configured to evaluate the harmonized digital signal and provide diagnostic information with respect to the transfer switch. For example, degradation of the switching speed over time.

In certain embodiments, the diagnostic device is selected from the group consisting of a microcontroller, a timer, a display, buttons, or combinations thereof. In some embodiments, the diagnostic device is selected from the group consisting of a microcontroller, a timer, or combinations thereof. In certain embodiments, the diagnostic device may further comprise a transmission device (e.g., transmission antenna) to transmit the diagnostic output.

In certain embodiments, a digital timer may be used in one embodiment as a diagnostic device to evaluate the switching speed of the transfer switch. For example, the time between the opening and closing of the one or more transfer switch contacts (e.g., the time the harmonized digital signal 225 takes to move from a first level to a second level), or vice versa.

In other embodiments, the systems and methods may comprise a diagnostic device comprising a processor and a memory coupled to the processor, the memory having computer-executable instructions stored thereon, wherein the instructions, when executed by the processor, cause the processor to evaluate and/or process the harmonized digital signal 225 and provide diagnostic information with respect to the transfer switch.

To further illustrate certain aspects of the present disclosure, the accompanying figures are discussed herein.

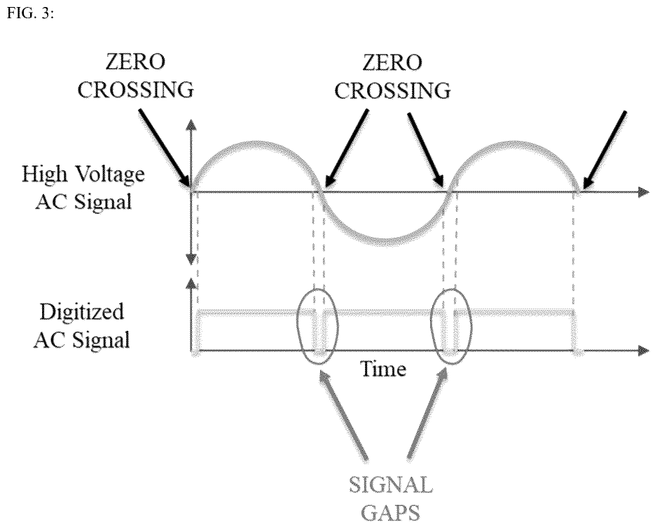

Analog signals from a device are useful for a number of purposes. However, the conversion of these analog signals to digital signals ultimately allows for greater manipulation, transferability, and composability, slower degradation, etc. of the data from the signals. FIG. 3 illustrates the problem encountered when converting an analog high voltage AC signal carried by a transfer switch to a digital AC signal. An analog high voltage AC signal exhibits the typical oscillation between negative and positive polarities over time. A conversion of an oscillating analog high voltage AC signal (top) to a digital AC signal (bottom) results in a digital graphical output that indicates whether the signal is in the on or off state. That is, the oscillating analog AC power signal is transformed into a binary digital signal. While the digital signal is more desirable for data processing and analysis, certain nuances may be lost in the conversion. For example, as the analog AC power signal transitions between polarities, it is present for a moment at a “zero” state. This is commonly referred to as the “zero crossing” and is illustrated in FIG. 3. When the analog signal is transformed to a digital signal, the zero crossing point is erroneously reported in the digital signal as being in the “off” state. This is particularly problematic when the signal is being evaluated for the change in electrical contact of a transfer switch (e.g., when the transfer switch moves the circuit from an on to an off state as it introduces a new power source). In a standard analog-digital conversion, the zero crossing would be incorrectly reported in the digital signal as a change in the electrical contact of the transfer switch. This makes evaluating a digital signal for change in electrical contact exceedingly difficult.

The inventors of the present disclosure have discovered methods, systems, and devices for evaluating the change in electrical contact of a transfer switch (e.g., when the switch is truly in an “off” state) while using an analog signal and overcoming the problems previously encountered in the field. In particular, the inventors have discovered that it is possible to correlate two or more phases from a multi-phase AC signal in order to eliminate the erroneous “off” readings at the zero crossing of the analog signal. For example, by preparing a harmonized digital signal that does not contain the zero crossing of a given phase.

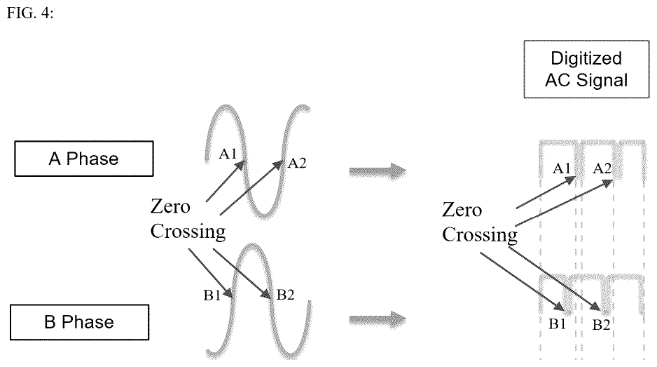

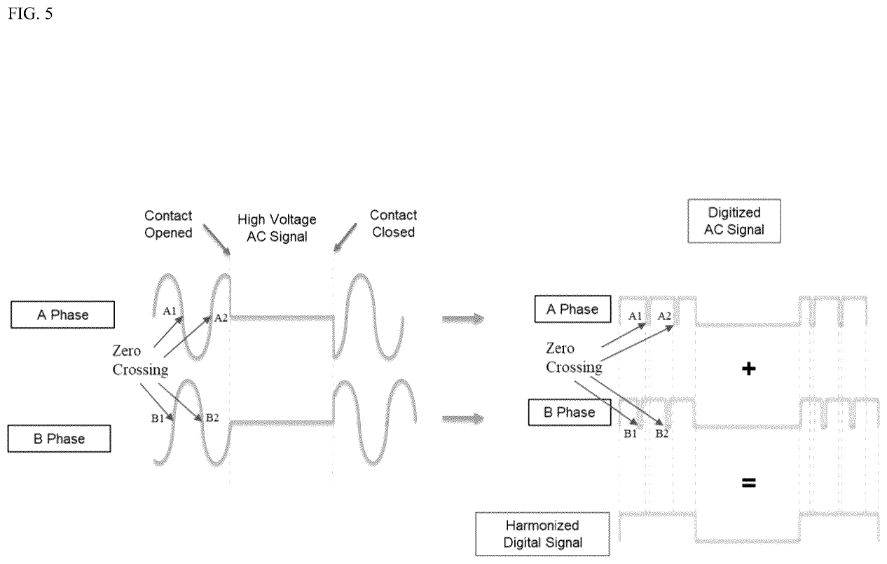

FIG. 4 shows two phases of a multi-phase analog high voltage AC signal (left), wherein the first phase is characterized as “A Phase” and the second phase is characterized as “B Phase.” The zero crossing points of each phase are noted on the graph. Time progresses along the x-axis of this figure, similar to FIG. 3. As shown in FIG. 4, each of the zero crossings occurs at slightly different points in time. That is, the zero crossings occur sequentially in time in the order of B1-A1-B2-A2.

The right side of FIG. 4 illustrates the digitized AC signals corresponding to each of Phase A and Phase B. The zero crossing points are more clearly seen in this digitized phase signal as occurring sequentially in time as B1-A1-B2-A2. By comparing at least two phases of the multi-phase AC signal, it is possible to locate where zero crossings are contained in the digital signal. That is, the slight variation in the timing of these zero crossings allows for a comparison of the digitized A Phase and B Phase and the creation of harmonized digital signal that is not corrupted by the zero crossings.

FIG. 5 illustrates an embodiment of the present disclosure wherein the at least two phases of the multi-phase AC signal can be compared to produce a “clean hot-hot” signal or harmonized digital signal that removes the erroneous readings represented by the zero crossings and reports only the change signal level of the digital signal due to a change in contact of the transfer switch.

FIG. 5 utilizes the same A Phase and B Phase signals as shown in FIG. 4.

However, in FIG. 5 the transfer switch electrical contact is opened and closed at the indicated points in time. In both the A Phase and B Phase analog signal, this is represented by a long zero reading. For purposes of illustration, this contact opening time is exaggerated to clearly delineate the time when the contact is opened and closed. However, if this contact switching time was shorter, it would be hard to distinguish between a zero reading of the zero crossings A1, A2, B1, and B2 or the zero reading attributable to the actual contact opening.

The present disclosure overcomes these issues by comparing at least two phases of the multi-phase AC signal in order to remove the zero crossings from the data. The A Phase and B Phase digitized graphs report the same zero readings during the contact opening. However, the zero crossing points A1 and A2 of the digitized Phase A signal are not present at the same point in time in the digitized Phase B signal. Similarly, the zero crossing points B1 and B2 of the digitized Phase B signal are not present at the same point in time in the digitized Phase A signal. Therefore, it is possible to prepare a clean hot-hot signal or harmonized digital signal that only contains a zero reading when both of the phases report a zero reading at that exact time. That is, a harmonized digital signal can be prepared wherein A1, A2, B1, and B2 are not present. This is illustrated on the right side of FIG. 5 by A Phase+B Phase=Harmonized digital Signal.

While the embodiment of FIG. 5 illustrates a method utilizing two phases of the AC signal to prepare a harmonized (clean hot-hot) signal, it will be understood that the present disclosure is applicable to any variation of the above-described method/system. That is, any multi-phase AC signal can be used in the described methods. For example, a two-phase, three-phase, etc. signal.

Regardless of the number of phases of the multi-phase AC signal carried by the transfer switch, it is important to the present methods, systems, and devices that at least two (i.e., two or more) of the phases be compared to one another to eliminate the erroneous “off” readings at the zero crossing and provide a harmonized digital signal wherein the actual switching of the transfer switch (i.e., change in contact) is reported by the change in level of the digital signal.

The embodiment of FIG. 5 reports zero crossings and openings of the transfer switch as “off” or low digital signal values and a closed transfer switch as “on” or high digital signal values. However, it will be understood that the same method may be employed where the signal is inverted. For example, where zero crossings and openings of the transfer switch are reported as high digital signal values. Therefore, the methods and systems herein may reference the levels of the digital signals agnostic to the normal or inverted status of the system. That is, the levels of the digital signals may be referred to herein as being present at either a “first” or “second” level. The methods and systems may otherwise operate in a manner consistent with the exemplary embodiment illustrated in FIG. 5.

Although discussion herein is directed to embodiments of a transfer switch, it will be understood that the described systems, methods, and devices are equally applicable to other devices (e.g., electromechanical devices) wherein the change in electrical contact can be evaluated by the existing high voltage multi-phase AC signal already present or carried by the device during standard operation. For example, the described systems, methods, and devices may be used to determine the operation timing of circuit breaker main contacts and/or the state of the circuit breaker main contacts (e.g., open or closed). In these other embodiments, it is possible to conduct the methods, arrange the systems, and utilize the diagnostic devices in substantially the same manner as described herein related to transfer switches to evaluate the change in electrical contact of the device.

Further, although discussion herein is directed to detecting and/or evaluating changes in electrical contact generally, it will be understood that such changes in electrical contact may take many forms and still be encompassed by the methods and systems described herein. For example, in certain embodiments, the change in electrical contact may be a change in a transfer switch electrical contact position (e.g., change in positioning of one or more of the electrical contacts of a transfer switch). In other embodiments, the change in electrical contact may be a change in the state of the transfer switch or device (e.g., change of the transfer switch state from open to close, or vice versa). Still further, in certain embodiments, the change in electrical contact may result from changes in, or operation of, a closed transition switch or an open transition switch.

In one aspect of the present disclosure, a method for detecting change in electrical contact of a transfer switch is presented. The method comprises evaluating a transfer switch which carries a high voltage multi-phase AC signal. Although discussion herein is directed to measuring a high voltage multi-phase AC signal carried by the transfer switch, it will be understood, as discussed in further detail above, that the AC signal may be measured at a corresponding control panel harness or transfer switch bus connected to the transfer switch. The method comprises measuring a first phase of the analog multi-phase AC signal and a second phase of the analog multi-phase AC signal. The measured analog first phase and measured analog second phase signals are digitized to create digitized first phase and digitized second phase signals. These two digitized phase signals are then compared to categorize the changes in level of the digital signal of each digitized phase signal as attributable to either the zero crossings of each respective digitized signal (i.e., a zero state present in only one of the digitized phase signals) or attributable to a change in contact of the transfer switch (i.e., a zero state present in both digitized phase signals).

In certain embodiments, the method further comprises preparing a harmonized digital signal wherein the harmonized digital signal does not contain a change in signal level corresponding to the zero crossing of the digitized first phase signal and/or digitized second phase signal. That is, the zero crossings of the first phase and the second phase are removed from consideration and a single harmonized digital signal is prepared that contains change(s) in digital signal level attributable only to change(s) in electrical contact of the transfer switch (i.e. switching of the transfer switch). For example, the harmonized digital signal may be prepared from the digitized first phase signal and digitized second phase signal using the following comparison: the harmonized digital signal is at a first level when the digitized first phase signal and digitized second phase signal are both at a first level, the harmonized digital signal is at a second level when the digitized first phase signal and digitized second phase signal are both at a second level, and the harmonized digital signal is at the first level when the digitized first phase signal and digitized second phase signal are at different levels.

In other embodiments, the present disclosure is directed to systems for evaluating the change in electrical contact of a transfer switch. The system comprises a transfer switch which carries an analog multi-phase AC signal; a measurement device configured to measure at least two phases of the analog multi-phase AC signal carried by the transfer switch (e.g., a first phase and a second phase of the analog multi-phase AC signal); an ADC device configured to convert the at least two measured phases of the analog multi-phase AC signal to their respective digitized phase signals; and a harmonization device comprising circuity configured to compare the at least two digitized phase signals to categorize a change in level of the digital signal as either attributable to a zero crossing of the digitized phase signal(s) or attributable to a switching in electrical contact position of the transfer switch. In certain embodiments, the circuitry of the harmonization device is further configured to combine the at least two digitized phase signals to produce a harmonized digital signal, wherein the harmonized digital signal does not contain changes in level of the harmonized digital signal attributable to the zero crossing of the at least two digitized phase signals. For example, the circuitry of the harmonization device may be configured to prepare a harmonized digital signal wherein the harmonized digital signal is at a first level when all of the at least two digitized phase signals are at a first level, wherein the harmonized digital signal is at a second level when all of the at least two digitized phase signals are at a second level, and wherein the harmonized digital signal is at a first level when two or more of the at least two digitized phase signals are at different levels.

Additional embodiments are directed to systems for evaluating the change in electrical contact of a transfer switch further comprising a diagnostic device. The diagnostic device comprises circuity configured to process and/or evaluate the harmonized digital signal.

The ADC device may be any device suitable for conversion of an analog AC signal to a digital AC signal. In certain embodiments, the systems, methods, and devices described herein comprise an ADC device that converts all measured phases of a multi-phase analog AC signal to their respective digital AC signals. For example, the ADC device may convert each of the first phase, second phase, etc. of the analog multi-phase AC signal carried by the transfer switch to their respective digitized first phase signal, digitized second phase signal, etc. in a single device. In other embodiments, the systems, methods, and devices described herein comprise an ADC device for each phase of a multi-phase analog AC signal. For example, a system may include a first ADC device that converts the first phase of the analog multi-phase AC signal carried by the transfer switch to a digitized first phase signal, a second ADC device that converts the second phase of the analog multi-phase AC signal carried by the transfer switch to a digitized second phase signal, etc.

One of the advantages of digitizing the multi-phase AC signal is that digital signals may be transmitted across farther distances with higher fidelity than analog signals. Therefore, in various aspects of the present disclosure, the measurement and digitization of the analog multi-phase AC signal carried by the transfer switch is conducted at a location immediately adjacent to the transfer switch.

The digitizing of the analog multi-phase AC signal at a location immediately adjacent to the transfer switch allows for minimal loss in quality and accuracy of the measurement that is digitized. That is, the signal is converted from an analog signal to a digital signal adjacent to the point of measurement of the signal. This allows for a near instantaneous conversion of the signal into a more robust and less corruptible digital signal, and minimizes the ability for the analog signal to be corrupted, interfered with, etc. prior to the conversion. For example, this measurement and digitization of the analog multi-phase AC signal may take place within 100 meters (m), 50 m, 25 m, 20 m, 10 m, 15 m, 5 m, or 1 m from the transfer switch. In other embodiments, the measurement and digitization may take place less than 1 m from the transfer switch.

As the digitized phase signals are of higher fidelity and can be transmitted across greater distances, the digitized phase signal can be transmitted to a location away from the transfer switch where there is adequate physical space and equipment for further processing and/or evaluation of the signals. In certain embodiments, the digitized phase signals may be transmitted to a location away from the transfer switch for harmonization and diagnostics. For example, the digitized phase signals may be transmitted to a location having adequate computing power and personnel to evaluate the signal, conduct remote diagnostics, and/or perform modeling of the system. In one embodiment, the digitized phase signals (i.e. digitized first phase signal, digitized second phase signal, etc.) may be transmitted to a location more than 50 m, more than 100 m, more than 250 m, more than 500 m, more than 1,000 m, or more than 1,500 m from the transfer switch.

As discussed elsewhere herein, it may be desirable in certain embodiments to compare the digitized phase signals resulting from the ADC device to determine the locations of the zero crossings and the locations of the switching of the transfer switch. It may also be desirable to prepare a harmonized digital signal from the digitized phase signals resulting from the ADC device. This comparison and categorization of the respective digitized phase signals and/or preparation of a harmonized digital signal may be achieved by a harmonization device. The harmonization device may be any device suitable for accomplishing the desired comparison, analysis, and preparation.

Still further embodiments of the present disclosure are directed to a harmonization device comprising circuity configured to: receive at least two digitized phase signals, wherein the at least two digitized phase signals are digitized from at least two phases of an analog multi-phase AC signal carried by a transfer switch; compare the at least two digitized phase signals; and prepare a harmonized digital signal. In certain embodiment the harmonized digital signal is at a first level when all of the at least two digitized phase signals are at a first level, is at a second level when all of the at least two digitized phase signals are at a second level, and is at a first level when two or more of the at least two digitized phase signals are at different levels.

For example, the harmonization device circuity may comprise a processor, an operational amplifier (opamp), an optical coupler (optocoupler), a transistor, a discrete logic gate, or combinations thereof.

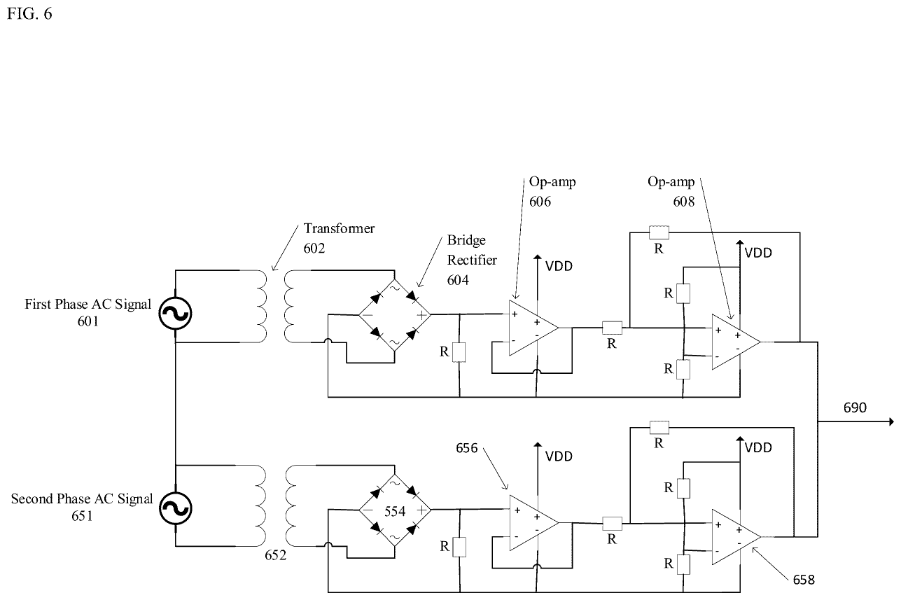

FIGS. 6-8 provide several exemplary circuity configurations for a harmonization device that is configured to compare a digitized first phase signal and a digitized second phase signal and prepare a harmonized digital signal.

FIG. 6 illustrates harmonization device circuity comprising a transformer, bridge rectifier, and several operational amplifiers (op-amps) for each phase signal. The configuration of FIG. 6 is commonly referred to as a “Schmitt Trigger” configuration. A first phase digital AC signal and second phase digital AC signal are provided at 601 and 651, respectively. Each digital phase signal is directed to a transformer 602/652, a bridge rectifier 604/654, and a series of op-amps 606/656 and 608/658. As illustrated, the circuitry comprises a number of resistors “R” and feedback loops such that a Schmitt Trigger configuration is formed. The circuitry of FIG. 6 produces a single harmonized digital signal 690.

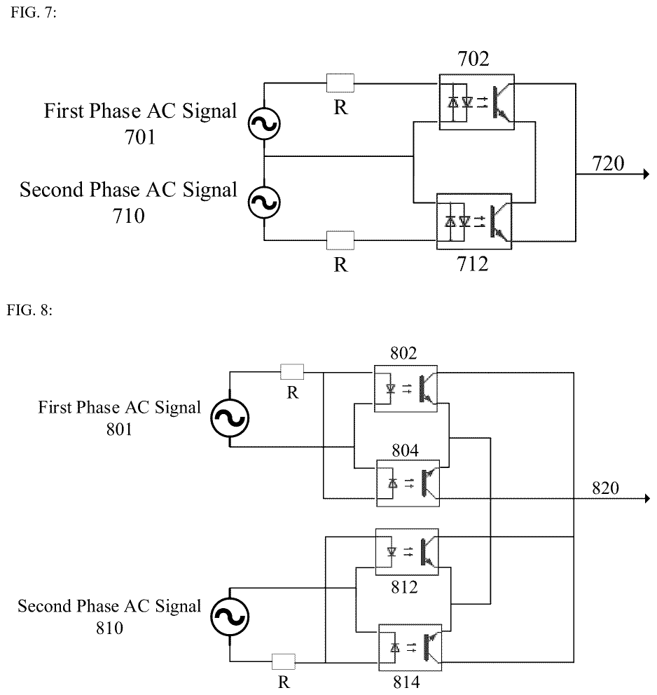

FIG. 7 illustrates harmonization device circuitry comprising bi-directional optocouplers. A first phase digital AC signal and second phase digital AC signal are provided at 701 and 710, respectively. Each digital phase signal is directed to a bi-directional optocoupler 702,712. As illustrated, the circuitry comprises a number of resistors “R” and connections between the bi-directional optical coupler (i.e. optocouplers). The circuitry of FIG. 7 produces a single harmonized digital signal 720.

FIG. 8 illustrates harmonization device circuitry comprising multiple optocouplers. A first phase digital AC signal and second phase digital AC signal are provided at 801 and 810, respectively. Each digital phase signal is directed to a first optocoupler 802/812 and second optocoupler 804/814. As illustrated, the circuitry comprises a number of resistors “R” and feedback loops. The circuitry of FIG. 8 produces a single harmonized digital signal 820.

Although FIGS. 6-8 provide exemplary harmonization device circuity configurations, it will be understood that any harmonization device or configuration may be utilized that allows for the comparison of two or more digital phase signals to prepare a harmonized digital signal. For example, a harmonization device comprising circuity comprises a processor, an operational amplifier (opamp), an optical coupler (optocoupler), a transistor, a discrete logic gate, or combinations thereof.

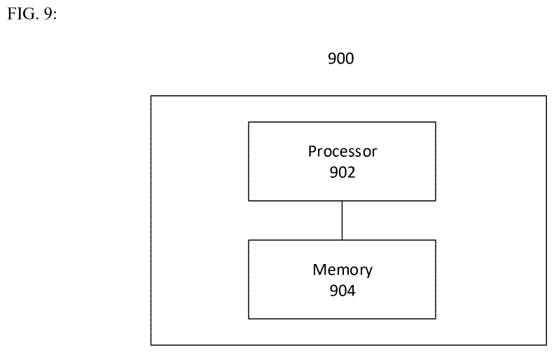

In one embodiment, as illustrated in FIG. 9, the harmonization device 900 comprises a processor 902 and a memory 904 coupled to the processor. The memory 904 has computer-executable instructions stored thereon. The instructions, when executed by the processor 902, cause the processor to compare the at least two digitized phase signals to classify the change in digital signal attributable to the zero crossings of each respective digitized phase signal and the change in digital signal attributable to change in contact of the transfer switch.

Similar to the ADC device, it may be desirable in certain embodiments for harmonization of the digital signals to take place at a location adjacent to the transfer switch. As noted previously, digital signals may be transmitted across farther distances with higher fidelity than analog signals. Preparation of the harmonized digital signal from the respective digitized phase signals at a location adjacent to the point of measurement/digitization similarly minimizes the possibility of interference or corruption of the digitized phase signals prior to harmonization.

Therefore, in some embodiments, the harmonization device is located within 100 m, 50 m, 25 m, 20 m, 15 m, 10 m, 5 m, or 1 m from the transfer switch. In other embodiments, the harmonization device is located within 100 m, 50 m, 25 m, 20 m, 15 m, 10 m, 5 m, or 1 m of the ADC.

In other embodiments, a harmonized digital signal is prepared from the digitized phase signals at a location between the transfer switch and ADC and the location wherein there is adequate physical space and equipment for evaluation of the signals. For example, in one embodiment, the harmonization device is located 5 m or greater, 10 m or greater, 15 m or greater, 20 m or greater, 25 m or greater, 50 m or greater, or 100 m or greater away from the ADC.

In other embodiments, a transfer switch diagnostic device may process or evaluate the harmonized digital signal produced from the harmonization device. The diagnostic device may comprise circuity configured to evaluate the harmonized digital signal. For example, evaluation of the harmonized digital signal to measure the time between an opening of the transfer switch contacts and a closing of the transfer switch contacts. In other embodiments, the diagnostic device is configured to evaluate the harmonized digital signal and provide diagnostic information with respect to the transfer switch.

In some embodiments, the harmonized digital signal may be used by the diagnostic device for further analysis, diagnostics, and predictive maintenance of the transfer switch and related systems.

As such, the harmonized digital signal may be transmitted to a location removed from the transfer switch and ADC for processing and/or evaluation by the diagnostic device. This transmittal to a remote location may allow for the harmonized digital signal to be evaluated at a location having enough physical space for the necessary equipment, at a central location wherein other harmonized digital signals from other devices are also transmitted, etc.

For example, the harmonized digital signal may be transmitted to a diagnostic device 5 m or greater, 10 m or greater, 15 m or greater, 20 m or greater, 25 m or greater, 50 m or greater, or 100 m or greater away from the harmonization device.

In certain embodiments wherein the ADC device and/or harmonization device are located adjacent to the transfer switch, it is possible to create and transmit the harmonized digital signal in a matter of seconds or less. That is, the near instantaneous conversion of the analog signal to a digital signal allows for closer to real-time data with respect to the transfer switch.

For example, in certain embodiments, the harmonized digital signal may be prepared in a period of less than about 10 seconds, less than about 5 seconds, less than about 1 second, less than about 0.5 seconds, less than about 0.01 seconds, less than about 5 milliseconds, less than about 1 millisecond, less than about 0.5 milliseconds, less than about 0.25 milliseconds, less than about 0.1 milliseconds, less than about 0.05 milliseconds, or less than about 0.01 milliseconds after measurement of the analog multi-phase AC signal carried by the transfer switch.

In other embodiments, the harmonized digital signal may be prepared and transmitted to a diagnostic device in a period of less than about 10 seconds, less than about 5 seconds, less than about 1 second, less than about 0.5 seconds, less than about 0.01 seconds, less than about 5 milliseconds, less than about 1 millisecond, less than about 0.5 milliseconds, less than about 0.25 milliseconds, less than about 0.1 milliseconds, less than about 0.05 milliseconds, or less than about 0.01 milliseconds after measurement of the analog multi-phase AC signal carried by the transfer switch.

As will be understood by those in the field, a harmonized digital signal representing the change in contact of a transfer switch (i.e. the change in level of the harmonized digital signal) may be useful for a number of analytical, diagnostic, etc. purposes.

In certain embodiments, the switching speed of the transfer switch can be monitored, which allows for the operator to evaluate the transfer switch in near real-time and take any corrective action that may be necessary.

In some embodiments, the harmonized digital signal may be evaluated by a diagnostic device to predict when the transfer switch will malfunction or operate outside of the intended parameters. The operator may then use this prediction to schedule appropriate servicing and maintenance of the transfer switch prior to the transfer switch malfunctioning or operating outside of the intended parameters.

In other embodiments, the harmonized digital signal may be used by a diagnostic device to monitor the status of a transfer switch and raise an alarm or trigger an emergency system when a change in electrical contact of the transfer switch is reported.

In further embodiments, the harmonized digital signal may be used by a diagnostic device to calculate the transfer switch's load transfer time. That is, the time it takes the transfer switch to transfer the load connection from first a first load source to a second load source, or vice-versa. For example, the time it takes to open and close the contact(s) of the transfer switch (e.g., as illustrated in FIG. 4).

Although discussion herein is directed to measuring the load transfer time, switching time, etc., it will be understood that the time of any other change in contact of the transfer switch may be similarly evaluated. For example, the change(s) in contact of a closed transition switch and/or open transition switch.

A closed transition switch first closes the electrical contacts and then opens one or more electrical contacts. The harmonized digital signal and/or diagnostic devices discussed herein may be used to calculate the time it takes the closed transition switch to initially close, to move from initially closed to open, and/or the time it takes the closed transition switch to complete all of the desired actions (i.e. initially close and then open). An open transition switch first opens the electrical contacts and then closes one or more electrical contacts. In certain embodiments, the harmonized digital signal and/or diagnostic devices discussed herein may be used to calculate the time it takes the open transition switch to initially open, to move from initially opened to closed, and/or the time it takes the open transition switch to complete all of the desired action (i.e. initially open and then close). Still further, the harmonized digital signal and/or diagnostic devices discussed herein may be used to calculate the time at which the closed/open transition switches begin and/or complete any of the above-noted actions.

In certain embodiments, the measured load transfer time, switching time, etc. can be used to determine whether the transfer switch is suitable for the intended system and/or to monitor the degradation of the transfer switch over time and evaluate when the transfer switch should be replaced.

In certain embodiments the above-described methods, systems, and devices may operate without hardware filtering of the signal(s). In other embodiments the above-described methods, systems, and devices may operate without the presence of a capacitor.

Although the methods, systems, and devices have been described herein as relating to testing and evaluating a transfer switch in operation, it is also possible to use the methods, systems, and devices to evaluate a transfer switch (or any other suitable device) for quality control after manufacturing. In this embodiment, the transfer switch may be connected to test circuits and power sources and subjected to the steps described herein. The digitized phase signals and/or harmonized digital signal may then be evaluated to determine the transfer speed of the transfer switch (e.g., the measured load transfer time, switching time, etc.). This information may be used to determine whether the transfer switch operates within the intended parameters (i.e., has the transfer speed desired) prior to integration of the transfer switch into a real circuit and/or sale or marketing of the transfer switch as having certain properties.

Embodiments of the aspects of the present disclosure may be described in the general context of data and/or processor-executable instructions, such as program modules, stored one or more tangible, non-transitory storage media and executed by one or more processors or other devices. Generally, program modules include, but are not limited to, routines, programs, objects, components, and data structures that perform particular tasks or implement particular abstract data types. Aspects of the present disclosure may also be practiced in distributed computing environments where tasks are performed by remote processing devices that are linked through a communications network. In a distributed computing environment, program modules may be located in both local and remote storage media including memory storage devices.

In operation, processors, computers and/or servers may execute the processor-executable instructions (e.g., software, firmware, and/or hardware) such as those illustrated herein to implement aspects of the invention.

Embodiments may be implemented with processor-executable instructions. The processor-executable instructions may be organized into one or more processor-executable components or modules on a tangible processor readable storage medium. Also, embodiments may be implemented with any number and organization of such components or modules. For example, aspects of the present disclosure are not limited to the specific processor-executable instructions or the specific components or modules illustrated in the figures and described herein. Other embodiments may include different processor-executable instructions or components having more or less functionality than illustrated and described herein.

The order of execution or performance of the operations in accordance with aspects of the present disclosure illustrated and described herein is not essential, unless otherwise specified. That is, the operations may be performed in any order, unless otherwise specified, and embodiments may include additional or fewer operations than those disclosed herein. For example, it is contemplated that executing or performing a particular operation before, contemporaneously with, or after another operation is within the scope of the invention.

Not all of the depicted components illustrated or described may be required. In addition, some implementations and embodiments may include additional components.

Variations in the arrangement and type of the components may be made without departing from the spirit or scope of the claims as set forth herein. Additional, different or fewer components may be provided and components may be combined. Alternatively, or in addition, a component may be implemented by several components.

The above description illustrates embodiments by way of example and not by way of limitation. This description enables one skilled in the art to make and use aspects of the invention, and describes several embodiments, adaptations, variations, alternatives and uses of the aspects of the invention, including what is presently believed to be the best mode of carrying out the aspects of the invention. Additionally, it is to be understood that the aspects of the invention are not limited in its application to the details of construction and the arrangement of components set forth in the following description or illustrated in the drawings. The aspects of the invention are capable of other embodiments and of being practiced or carried out in various ways. Also, it will be understood that the phraseology and terminology used herein is for the purpose of description and should not be regarded as limiting.

Having described the present disclosure in detail, it will be apparent that modifications and variations are possible without departing from the scope defined in the appended claims.

When introducing elements of the present disclosure or the preferred embodiments(s) thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that the several objects of the disclosure are achieved and other advantageous results attained.

As various changes could be made in the above methods, systems, and constructions without departing from the scope of the disclosure, it is intended that all matter contained in the above description and shown in the accompanying drawings shall be interpreted as illustrative and not in a limiting sense.

The Abstract and Summary are provided to help the reader quickly ascertain the nature of the technical disclosure. They are submitted with the understanding that they will not be used to interpret or limit the scope or meaning of the claims. The Summary is provided to introduce a selection of concepts in simplified form that are further described in the Detailed Description. The Summary is not intended to identify key features or essential features of the claimed subject matter, nor is it intended to be used as an aid in determining the claimed subject matter.

1. A method for detecting change in electrical contact of a transfer switch, wherein the transfer switch carries an analog multi-phase alternating current (AC) signal, the method comprising:
measuring a first phase of the analog multi-phase AC signal from the transfer switch;
measuring a second phase of the analog multi-phase AC signal from the transfer switch;
digitizing the measured analog first phase signal and the measured analog second phase signal to create a digitized first phase signal and a digitized second phase signal, respectively; and
preparing a harmonized digital signal from the digitized first phase signal and digitized second phase signal:
wherein the harmonized digital signal is at a first level when the digitized first phase signal and digitized second phase signal are both at a first level;
wherein the harmonized digital signal is at a second level when the digitized first phase signal and digitized second phase signal are both at a second level; and
wherein the harmonized digital signal is at the first level when the digitized first phase signal and digitized second phase signal are at different levels.

2. The method of claim 1, wherein the first level represents a high digital signal and the second level represents a low digital signal.

3. The method of claim 1, wherein a change of the harmonized digital signal from the first level to the second level represents an opening of one or more contacts of the transfer switch, and a change of the harmonized digital signal from the second level to the first level represents a closing of one or more contacts of the transfer switch.

4. The method of claim 3, further comprising determining the switching speed of the transfer switch, wherein determining the switching speed comprises measuring the time it takes to transfer the load connection from a first load source to a second load source, or vice versa.

5. The method of claim 4, wherein the time is measured utilizing one or more of a microcontroller, a timer, a display, buttons, or combinations thereof.

6-11. (canceled)

12. A harmonization device comprising circuity configured to:
receive a first phase digital signal and second phase digital signal, wherein the first phase digital signal and second phase digital signal are digitized from a first phase analog signal and a second phase analog signal, respectively, of an analog multi-phase alternating current (AC) signal carried by a transfer switch;
compare the digitized first phase signal and digitized second phase signal; and
prepare a harmonized digital signal:
wherein the harmonized digital signal is at a first level when the digitized first phase signal and digitized second phase signal are both at a first level;
wherein the harmonized digital signal is at a second level when the digitized first phase signal and digitized second phase signal are both at a second level; and
wherein the harmonized digital signal is at the first level when the digitized first phase signal and digitized second phase signal are at different levels.

13. The harmonization device of claim 12, wherein the circuity is further configured to evaluate the harmonized digital signal and provide diagnostic information with respect to the transfer switch.

14. The harmonization device of claim 12, wherein the circuity comprises a processor, an operational amplifier (opamp), an optical coupler, a transistor, a discrete logic gate, or combinations thereof.

15. The harmonization device of claim 12, wherein the circuity comprises a microprocessor.

16. The harmonization device of claim 12, wherein the circuity comprises a processor and a memory coupled to the processor, the memory having computer-executable instructions stored thereon, wherein the instructions, when executed by the processor, cause the processor to receive, compare, and prepare.

17. A system for evaluating the change in electrical contact of a transfer switch, wherein the transfer switch carries an analog multi-phase alternating current (AC) signal and the system comprises:
a measurement device configured to measure a first phase and a second phase of the analog multi-phase AC signal carried by the transfer switch;
an analog-to-digital conversion device configured to convert the measured analog first phase signal and the measured analog second phase signal to a digitized first phase signal and a digitized second phase signal, respectively; and
a harmonization device comprising circuity configured to compare the digitized first phase signal and the digitized second phase signal and prepare a harmonized digital signal:
wherein the harmonized digital signal is at a first level when the digitized first phase signal and digitized second phase signal are both at a first level;
wherein the harmonized digital signal is at a second level when the digitized first phase signal and digitized second phase signal are both at a second level; and
wherein the harmonized digital signal is at the first level when the digitized first phase signal and digitized second phase signal are at different levels.

18. The system of claim 17, wherein the circuity comprises a processor, an opamp, an optical coupler, a transistor, a discrete logic gate, or combinations thereof.

19. The system of claim 18, wherein the circuity comprises a processor and a memory coupled to the processor, the memory having computer-executable instructions stored thereon, wherein the instructions, when executed by the processor, cause the processor to compare the digitized signals and prepare the harmonized digital signal.

20. The system of claim 17, wherein the first level represents a high digital signal and the second level represents a low digital signal, a change of the harmonized digital signal from the first level to the second level represents an opening of one or more contacts of the transfer switch, and a change of the harmonized digital signal from the second level to the first level represents a closing of one or more contacts of the transfer switch.

21. The system of claim 17, wherein the first level represents a low digital signal and the second level represents a high digital signal, a change of the harmonized digital signal from the second level to the first level represents an opening of one or more contacts of the transfer switch, and a change of the harmonized digital signal from the first level to the second level represents a closing of one or more contacts of the transfer switch.

22. The system of claim 17, wherein the system further comprises a diagnostic device comprising circuity configured to evaluate the harmonized digital signal.

23. The system of claim 22, wherein the diagnostic device comprises circuity configured to measure the switching speed of the transfer switch, wherein measuring the switching speed comprises measuring the time it takes to transfer the load connection from a first load source to a second load source, or vice versa.

24. The system of claim 22, wherein diagnostic device is configured to evaluate the harmonized digital signal and provide diagnostic information with respect to the transfer switch.

25. The system of claim 22, wherein the diagnostic device is selected from the group consisting of a microcontroller, a timer, a display, buttons, or combinations thereof.

26. The system of claim 17, where the harmonized digital signal is prepared in a period of less than about 10 seconds, less than about 5 seconds, less than about 1 second, less than about 0.5 seconds, less than about 0.01 seconds, less than about 5 milliseconds, less than about 1 millisecond, less than about 0.5 milliseconds, less than about 0.25 milliseconds, less than about 0.1 milliseconds, less than about 0.05 milliseconds, or less than about 0.01 milliseconds after measurement by the measurement device of the first phase and a second phase of the analog multi-phase AC signal carried by the transfer switch.
